(19) United States
(12) Patent Application Publication
(10) Pub. No.: US 2012/0097974 A1
(43) Pub. Date: Apr. 26, 2012

(54) POWER SEMICONDUCTOR DEVICE

(75) Inventor: Muhammad NAWAZ, Klofta (NO)

(73) Assignee: UNIVERSITETSSENTERET PÅ KJELLER (UNIK), Kjeller (NO)

(21) Appl. No.: 12/908,316

(22) Filed: Oct. 20, 2010

(51) Int. Cl. H01L 29/24; H01L 21/8222

(52) U.S. Cl. 257/77; 438/309; 257/E29.104; 257/E21.608

(57) ABSTRACT

A method and apparatus for achieving high current gain, and low on-resistance, from a Bipolar Junction Transistor (BJT) in high temperature and high power applications are disclosed. In some embodiments, a thin doped delta layer is inserted at the base emitter junction but inside the base layer. In addition, in some embodiments, a surface recombination layer is inserted between the emitter-base regions of the device. In some embodiments, use of an ion implantation step is avoided to achieve simplicity and low cost of manufacture.

### CROSS-REFERENCE TO RELATED APPLICATION

n/a

### STATEMENT REGARDING FEDERALLY SPONSORED RESEARCH OR DEVELOPMENT

n/a

### FIELD OF THE INVENTION

The present invention relates to a method and apparatus for achieving high current gain, and low on-resistance, from a Bipolar Junction Transistor (BJT) in high temperature and high power applications.

### BACKGROUND OF THE INVENTION

Silicon carbide (SiC) based semiconductor electronic devices and circuits are presently being developed for use in high-temperature, high-power, and/or high-radiation conditions under which conventional semiconductors on a silicon (Si) substrate cannot adequately perform. Presently, most power electronics converter systems in automotive applications use silicon-(Si) based power semiconductor switches. The performance of these systems is approaching the theoretical limits of the fundamental material properties of the Si. The emergence of silicon carbide-(SiC) based power semiconductor switches likely will result in substantial improvements in the performance of power electronics converter systems in transportation applications. SiC-based power switches can be used in electric traction drives and other automotive electrical subsystems, as well as other applications, with advantages over Si-based switches.

Compared to conventional Si material, which is used today for standard CMOS and power applications from 25 to 100° C., silicon carbide (SiC) is a wide bandgap material (3 times that of Si) having larger thermal conductivity values (3 times that of Si), larger breakdown field strength (10 times that of Si) and offer larger carrier saturation velocity (2 times that of Si). Because of these unique features, SiC material is well-suited for high power devices in a temperature range of −75 to 550° C.

Silicon carbide based three terminal devices such as MOSFETs (metal oxide semiconductor field effect transistors), JFETs (Junction field effect transistors), and BJTs (Bipolar junction transistors) are basic building blocks in a variety of circuits for high power and high temperature applications. Discrete devices (i.e., MOSFETs, JFETs and BJTs) have been tested using silicon carbide material at very high temperatures. The development of SiC MOSFETs is primarily limited by the low channel mobility and unreliability of the gate oxide. The JFETs are normally-on devices and raise concerns for hybrid electric vehicle (HEV) applications due to the risk of driver supply voltage failure. A remaining favorable option for the application of SiC devices are BJTs because they are intrinsically normally-off devices, free from gate oxide growth problems, and have fast switching speed and lower power losses.

With the availability of defect-free, high quality 2 to 4″ (inch) substrates, manufacturing of high-quality, large-area power devices using SiC is now possible. SiC exists in many forms, including common crystal polytypes such as 4H-SiC, 6H-SiC and 3C-SiC. The electron and hole mobility values of 4H-SiC lie around 950 and 120 cm²/V.sec, respectively. Also, 4H-SiC material is being developed for power devices by several manufacturers.

Various technological design concepts such as implantation free BJTs, graded base BJTs, regrown extrinsic p⁺ base layer and suppressed surface recombination (SSR) BJTs have been explored with novel surface passivation methodologies. With current designs, the maximum current gain (β=I_{C}/I_{B}: collector current/base current) achieved so far lies in the range of between 31-134, at room temperature.

The base ion implantation process is well-known to generate life time killing defects (crystalline damage) in the bulk base region and surface region of SiC close to the base contact. This leads to enhanced base recombination current which decreases the current gain (β). Also, ion implantation requires an extra high temperature annealing step for dopant activation, which is difficult to optimize for complete activation of dopant atoms. While a suppressed surface recombination concept presents fairly improved performance (i.e., β=134 and R_{ON}=3.2 Ω-cm²), the blocking voltage capability is only about 1000V. Further, the use of a thin base layer of only 100 nm may pose a base punch through problem. Also, precise control of such complex manufacturing processes is extremely difficult for the formation of a thin highly resistive p-type (HRP) layer within the emitter-base region in a lightly doped n-type SiC layer. This demands the use of extra low dose Al implants followed by activation annealing to get an acceptor concentration in the range of 0.1−1×10¹⁶ cm⁻³.

Generally speaking, the current gain (β) in SiC BJTs is primarily limited by the recombination of carriers at the surface, which still remains one of the critical issues for SiC BJT design. What is needed is a fast-switching SiC BJT with high current gain and low on-resistance for high temperature and high power applications that can be manufactured at relatively low cost.

### SUMMARY OF THE INVENTION

The present invention advantageously provides a method for making a bipolar junction transistor on a doped silicon carbide (SiC) substrate. According to one aspect, the invention provides a method that includes growing at least one collector layer, and on the collector layer, growing a base layer, and on the base layer, growing a doped delta layer, and on the doped delta layer, growing an emitter structure. The method may further comprise growing a surface recombination passivation layer on the doped delta layer.

According to another aspect, the invention provides a bipolar junction transistor on a doped silicon carbide (SiC) substrate. The transistor includes a base layer, an emitter layer, and a collector layer. The transistor further includes a doped delta layer at the interface of the emitter layer and the base layer, the doped delta layer located within the base layer. The transistor may also include a surface recombination passivation layer positioned above the doped delta layer and between a region of the emitter and a base contact region.

According to another aspect, the invention provides a bipolar junction transistor on an n-type doped 4H-SiC substrate. The transistor includes a first collector layer of n-type doped silicon carbide on or above the 4H-SiC substrate. The transistor also includes a second collector layer of lightly n-type doped silicon carbide on the first collector layer. A first p-type doped silicon carbide base layer is on the second collector layer. A second p-type doped delta layer at the interface of an emitter layer and the base layer is located inside the base layer. The transistor also includes a third n-type doped silicon carbide emitter layer on the p-type doped base layer. In some embodiments, the transistor also includes a p-type surface recombination passivation layer of silicon carbide material over the doped delta layer in a region of the base layer and emitter layer.

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 is a simplified diagram of a prior art NPN type 4H-SiC BJT device 100;

FIG. 2 is a diagram of an NPN type 4H-SiC BJT device 200 constructed in accordance with the principles described herein;

FIG. 3 illustrates the current gain at 300 K as a function of collector current density for the reference design of FIG. 1, for a design having an added delta layer, and for a design having both an added delta layer and a surface recombination (SR) passivation layer; and

FIG. 4 illustrates current gain as function of temperature for the reference design of FIG. 1, for the design having the added delta layer, and for the design having both an added delta layer and a surface recombination (SR) passivation layer.

### DETAILED DESCRIPTION OF THE INVENTION

A method and apparatus for achieving high current gain, and low on-resistance, from a Bipolar Junction Transistor (BJT) in high temperature and high power applications are disclosed. In some embodiments, a thin doped delta layer is inserted at the base emitter junction but inside the base layer. In addition, in some embodiments, a surface recombination layer is inserted between the emitter-base regions of the device. In some embodiments, use of an ion implantation step is avoided to achieve simplicity and low cost of manufacture.

Before describing in detail exemplary embodiments that are in accordance with the present invention, it is noted that the embodiments reside primarily in combinations of apparatus components and processing steps related to bipolar transistor manufacture. Accordingly, the system and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements.

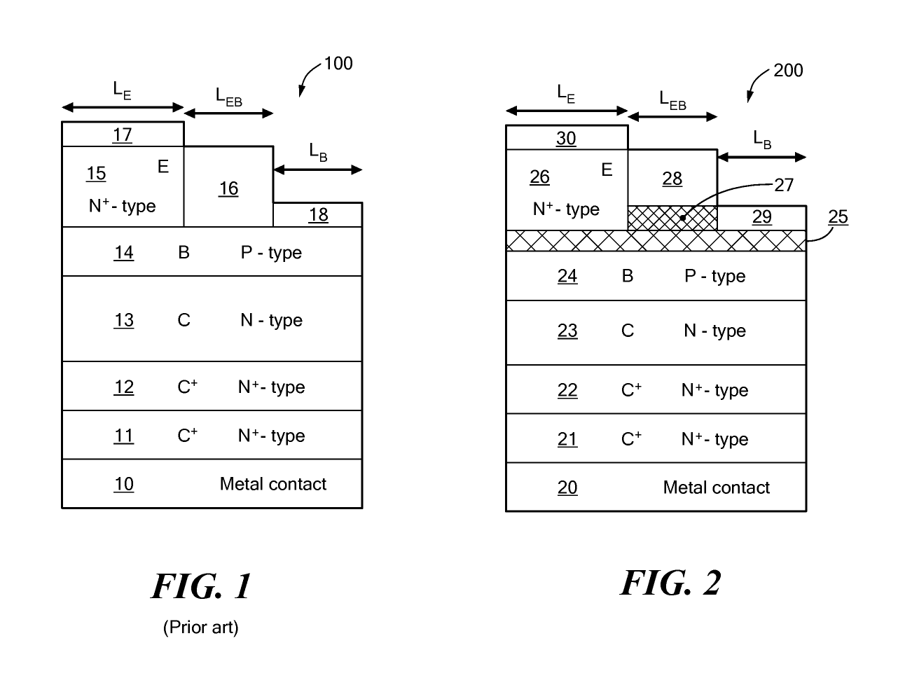

FIG. 1 is a simplified diagram of a prior art NPN type 4H-SiC BJT device 100. The prior art structure is composed of high n-type doped bottom collector layers 11 and 12, a low doped n-type subcollector layer 13, a thin p-type doped base layer 14 and a top n-type doped emitter layer 15. The bottom collector layer 11 may be a high n-type doped (N_{d}=1-2×10¹⁹ cm⁻³) substrate of thickness 200-500 μm. The thickness of the collector layer 12 may be 1 μm with n-type doping of 1×10¹⁹ cm⁻³. The thickness of the subcollector layer 13 may be 10-15 μm with n-type doping of 0.1-5×10¹⁶ cm⁻³. The thickness of the base layer 14 may be 0.5-1 μm with p-type doping of 0.5-1×10¹⁷ cm⁻³. Finally, the thickness of the top emitter layer 15 may be 1-2 μm with n-type doping of 1-2×10¹⁹ cm⁻³. The whole epitaxy structure is grown in a single step using molecular beam epitaxy (MBE) or metal organic chemical vapor deposition (MOCVD) techniques on 4H-SiC substrate. The metal contact layers are 10 (bottom collector contact), 17 (top emitter contact) and 18 (base contact).

The layer 16 forms a passivation insulating layer made of a dielectric material such as SiO₂ or Si₃N₄ to protect the device surface. The passivation layer should be of high quality (i.e., minimum interface state density) and grown or deposited over a SiC surface. The L_{E}, L_{EB} and L_{B} parameters are the emitter width (2-5 μm), emitter-base distance (5-10 μm) and base width (2-5 μm), respectively. Some manufacturing processes of the prior art may include a base implantation step followed by activation annealing for reducing base resistance and, hence, achieving low on-resistance.

FIG. 2 is a diagram of an NPN type 4H-SiC BJT device 200 constructed in accordance with the principles described herein. The structure is composed of high n-type doped bottom collector layers 21 and 22, a low doped n-type subcollector layer 23, a thin p-type doped base layer 24 and a top n-type doped emitter layer 26. A thin highly doped delta layer 25 is inserted at the base-emitter junction but inside the base layer 24. The whole epitaxy base structure 22, 23, 24, 25, 26 may be grown in a single step using molecular beam epitaxy (MBE) or metal organic chemical vapor deposition (MOCVD) techniques on 4H-SiC substrate (21).

The bottom collector layer 21 may be a high n-type doped (N_{d}=1-2×10¹⁹ cm⁻³) substrate of thickness 200-500 μm. The thickness of the collector layer 22 is 1-2 μm with n-type doping of 1-2×10¹⁹ cm⁻³. The thickness of the subcollector layer 23 may be 10-15 μm with n-type doping of 0.1-5×10¹⁶ cm⁻³. The thickness of the base layer 24 may be 0.4-0.7 μm with uniform p-type doping of 1×10¹⁷ cm⁻³. The thickness of the delta layer 25 may be 5-15 nm with p-type doping of 0.5-1.0×10¹⁹ cm⁻³. Finally, the thickness of the top emitter layer 26 may be 1-1.5 μm with n-type doping of 1-2×10¹⁹ cm⁻³. The metal contact layers are 20 (bottom collector contact), 30 (top emitter contact) and 29 (base contact). The bottom collector metal layer 20 may be of Ni/Au material while the top emitter layer 30 and base layer 29 may be of Ni/Ti/Al and Ni/Al material system respectively.

A thin high p-type doped layer 27 of SiC material is regrown between the base-emitter regions after an emitter mesa etch definition step. The thickness of this regrown surface recombination (SR) passivation layer 27 over the SiC surface may be 40-60 nm with p-type doping concentration of 0.5-1.0×10¹⁹ cm⁻³. The passivation layer 27 is regrown selectively by MBE or MOCVD between the base-emitter region while protecting the other areas of the device surface by suitable dielectric mask. Finally the gap between the base-emitter regions is filled by a suitable dielectric layer 28 of SiO₂ or Si₃N₄ material. The p-type doped passivation layer 27 should be of high quality (i.e., minimum interface state density) and grown over SiC surface. The L_{E}, L_{EB}, and L_{B} parameters are the emitter width (2-5 μm), emitter-base distance (5-10 μm) and base width (2-5 μm), respectively. Note that the proposed structure does not include any implantation step in order to reduce the cost of manufacturing the device.

The design described above, having the SiC based delta layer 25 and surface recombination passivation layer 27, reduces the surface recombination rate along the lateral direction within the base-emitter region due to the blockage of injected electrons towards the surface of the base-emitter region. For this reason (i.e., reduced surface recombination), the embodiment of FIG. 2 produces significantly increased current gain, as compared to the prior art embodiment of FIG. 1. Moreover, very low on-resistance of 4.0 mΩ-cm² has been achieved with the proposed design since the top surface region of the base is highly p-type doped. Note that the doped delta layer and the SR passivation layers may be formed without ion implantation using one of a molecular beam epitaxy process and a metal organic chemical vapor deposition process.

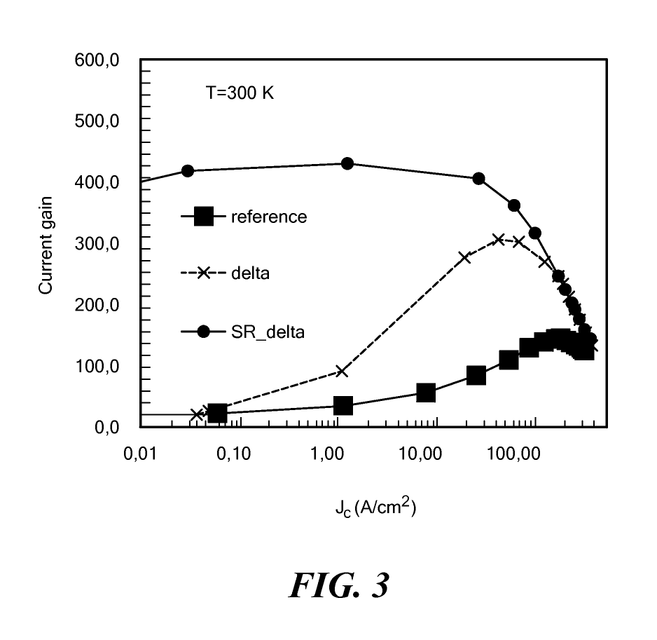

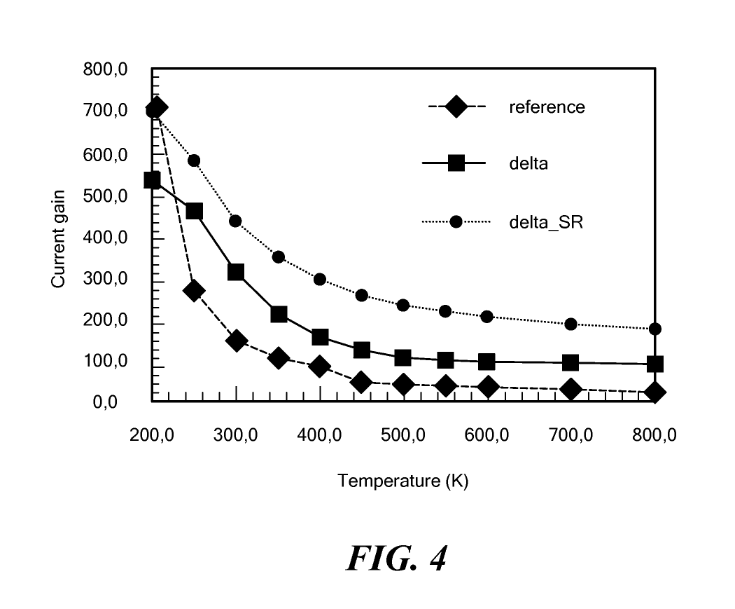

FIG. 3 illustrates the current gain at 300 K as a function of collector current density for the reference design of FIG. 1, (i.e., the prior art), for the design having the added delta layer 25, and for the design having both the added delta layer 25 and the surface recombination (SR) passivation layer 27. Current gain at various temperatures is also presented in FIG. 4 for the reference design, for the design having the added delta layer 25, and for the design having both the added delta layer and the SR passivation layer 27. Superior performance is achieved over a wide temperature range with only delta layer 25 and with the combined delta and passivation layers (i.e., layers 25 and 27). In FIG. 3 and FIG. 4, the delta layer 25 is 10 nm thick with a p-type doping of 1.0×10¹⁹ cm⁻³. The SR-passivation layer 27 is 60 nm thick with p-type doping of 1.0×10¹⁹ cm⁻³.

Thus, with a doped delta layer without the SR passivation layer, at 300 Kelvin, the transistor exhibits a current gain exceeding about 200 at a collector current density in a range of about 10 to 100 amperes/cm², as shown in FIG. 3. With both a doped delta layer and the SR passivation layer, at 300 Kelvin, the bipolar junction transistor exhibits a current gain exceeding about 400 at a collector current density in a range of about 1 to 10 amperes/cm², also as shown in FIG. 3.

As shown in FIG. 4, with a doped delta layer without the SR passivation layer, the transistor exhibits a current gain exceeding about 400 at a temperature in a range of about 200 to 300 Kelvin. With both a doped delta layer and the SR passivation layer, the transistor exhibits a current gain exceeding about 300 at a temperature in a range of about 200 to 300 Kelvin.

Compared to conventional BJT design, such as shown in FIG. 1, embodiments described with reference to FIGS. 2-4, present high gain and low on-resistance, due to the thin high doped layer underneath the base contact, and a defect-free SiC base surface. Note that no extra base implantation or activation annealing is needed, and hence, the manufacture of the device is a simple and low cost process. From the viewpoint of achieving maximum current gain and simultaneously keeping technological control, a 10 nm thick delta layer with doping of 5×10¹⁸ cm⁻³ presents a balanced choice.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. A bipolar junction transistor on a doped silicon carbide (SiC) substrate, comprising:
a collector layer;
a base layer;
an emitter layer; and
a doped delta layer at the interface of the emitter layer and the base layer, the doped delta layer located within the base layer.

2. The bipolar junction transistor of claim 1, further comprising a surface recombination passivation layer positioned above the doped delta layer and between a region of the emitter and a base contact region.

3. The bipolar junction transistor of claim 2, wherein the surface recombination passivation layer has a thickness in the range of 40 to 60 nanometers.

4. The bipolar junction transistor of claim 3, wherein the surface recombination passivation layer has a doping concentration in the range of 0.5-1.0×10¹⁹ cm⁻³.

5. The bipolar junction transistor of claim 2, wherein the surface recombination passivation layer has a doping concentration in the range of 0.5-1.0×10¹⁹ cm⁻³.

6. The bipolar junction transistor of claim 1, wherein the doped delta layer has a thickness in the range of 5 to 15 nanometers.

7. The bipolar junction transistor of claim 6, wherein the doped delta layer has a doping concentration in the range of 0.5-1.0×10¹⁹ cm⁻³.

8. The bipolar junction transistor of claim 1, wherein the doped delta layer has a doping concentration in the range of 0.5-1.0×10¹⁹ cm⁻³.

9. The bipolar junction transistor of claim 1, wherein the SiC substrate is 4H-SiC.

10. A method for making a bipolar junction transistor, the method comprising:
forming at least one collector layer, and on the collector layer, forming a base layer, and on the base layer, forming a doped delta layer, and on the doped delta layer, forming an emitter structure.

11. The method of claim 10, further comprising forming a surface recombination passivation layer on the doped delta layer adjacent to the emitter structure.

12. The method of claim 11, wherein forming the surface recombination passivation layer is performed without ion implantation using one of a molecular beam epitaxy process and a metal organic chemical vapor deposition process.

13. The method of claim 11, wherein the bipolar junction transistor exhibits, at 300 Kelvin, a current gain exceeding about 400 at a collector current density in a range of about 1 to 10 amperes/cm².

14. The method of claim 11, wherein the bipolar junction transistor exhibits a current gain exceeding about 400 at a temperature in a range of about 200 to 300 Kelvin.

15. The method of claim 10, wherein forming the doped delta layer is performed without ion implantation using one of a molecular beam epitaxy process and a metal organic chemical vapor deposition process.

16. The method of claim 10, wherein the bipolar junction transistor exhibits, at 300 Kelvin, a current gain exceeding about 200 at a collector current density in a range of about 10 to 100 amperes/cm².

17. The method of claim 10, wherein the bipolar junction transistor exhibits a current gain exceeding about 300 at a temperature in a range of about 200 to 300 Kelvin.

18. A bipolar junction transistor on an n-type doped 4H-SiC substrate, the transistor comprising:
a first collector layer of n-type doped silicon carbide on or above the 4H-SiC substrate;
a second collector layer of lightly n-type doped silicon carbide on the first collector layer;
a first p-type doped silicon carbide base layer on the second collector layer;
a second p-type doped delta layer at the interface of an emitter layer and the base layer but located inside the base layer;
a third n-type doped silicon carbide emitter layer on the p-type doped base layer;

19. The bipolar junction transistor of claim 18, further comprising a p-type surface recombination passivation layer of silicon carbide material over the doped delta layer in a region of the base layer and emitter layer.

20. The bipolar junction transistor of claim 18, wherein the surface recombination passivation layer has a width in the range of 5-10 micrometers.
